(19) United States
(12) Patent Application Publication
(10) Pub. No.: US 2016/0056165 A1
(43) Pub. Date: Feb. 25, 2016

(54) SEMICONDUCTOR DEVICE AND METHOD OF MANUFACTURING THE SAME

(71) Applicant: KABUSHIKI KAISHA TOSHIBA, Minato-ku (JP)

(72) Inventor: Kappei IMAMURA, Yokkaichi (JP)

(73) Assignee: KABUSHIKI KAISHA TOSHIBA, Minato-ku (JP)

(21) Appl. No.: 14/621,804

(22) Filed: Feb. 13, 2015

(30) Foreign Application Priority Data
Aug. 25, 2014 (JP) 2014-170759

(51) Int. Cl. H01L 27/115; H01L 21/311; H01L 21/28

(52) U.S. Cl. CPC H01L 27/11573; H01L 27/11582; H01L 27/11568; H01L 21/28282; H01L 21/31116

(57) ABSTRACT

In one embodiment, a method of manufacturing a semiconductor device includes alternately forming plural first insulators and plural first films on a substrate, and etching the first insulators and the first films to form a contact region having first to N-th upper faces whose heights are mutually different where N is an integer of two or more. The method further includes forming a second insulator containing boron or hafnium on the first to N-th upper faces, forming a third insulator on the second insulator, and forming plural electrode layers between the plural first insulators. The method further includes etching the second and third insulators to form first to N-th contact holes respectively reaching the electrode layers under the first to N-th upper faces, and forming first to N-th contact plugs in the first to N-th contact holes respectively.

### CROSS REFERENCE TO RELATED APPLICATION

This application is based upon and claims the benefit of priority from the prior Japanese Patent Application No. 2014-170759, filed on Aug. 25, 2014, the entire contents of which are incorporated herein by reference.

### FIELD

Embodiments described herein relate to a semiconductor device and a method of manufacturing the same.

### BACKGROUND

For example, a three-dimensional memory has a structure in which plural insulators and plural electrode layers are alternately stacked on a substrate. The electrode layers function as word lines or select lines. When such a three-dimensional memory is formed, a step-shaped contact region (step region) is formed to form contact plugs on the electrode layers.

In this case, there is a problem that an aspect ratio of a contact hole for a lower electrode layer is remarkably different from an aspect ratio of a contact hole for an upper electrode layer. If an etching condition for contact processing is adjusted to the lower electrode layer, the contact hole for the upper electrode layer does not penetrate up to the upper electrode layer and therefore a contact failure may occur. On the other hand, if the etching condition is adjusted to the upper electrode layer, excessive over-etching may be caused in the contact hole for the lower electrode layer and therefore the electrode layers may be short-circuited between them. Although these problems can be solved by forming the contact holes with individual etching, this causes a problem of an increase of the number of steps.

In order to solve the problems, a stopper film for the contact processing may be formed on the step region. In this case, when films between the insulators are replaced with the electrode layers, the stopper film may be removed together with these films and therefore the electrode layers may be short-circuited between them.

### BRIEF DESCRIPTION OF THE DRAWINGS

FIG. 1 is a cross-sectional view illustrating a structure of a semiconductor device of a first embodiment;

FIG. 2A to FIG. 5B are cross-sectional views illustrating a method of manufacturing the semiconductor device of the first embodiment;

FIG. 6 is a cross-sectional view illustrating a structure of a semiconductor device of a second embodiment;

FIG. 7A to FIG. 10B are cross-sectional views illustrating a method of manufacturing the semiconductor device of the second embodiment;

FIG. 11 is a cross-sectional view illustrating a structure of a semiconductor device of a third embodiment;

FIG. 12A to FIG. 15C are cross-sectional views illustrating a method of manufacturing the semiconductor device of the third embodiment; and

FIG. 16 is a cross-sectional view illustrating a structure of a semiconductor device of a modification of the first embodiment.

### DETAILED DESCRIPTION

Embodiments will now be explained with reference to the accompanying drawings.

In one embodiment, a method of manufacturing a semiconductor device includes alternately forming plural first insulators and plural first films on a substrate, and etching the first insulators and the first films to form a contact region having first to N-th upper faces whose heights are mutually different where N is an integer of two or more. The method further includes forming a second insulator containing boron or hafnium on the first to N-th upper faces, forming a third insulator on the second insulator, and forming plural electrode layers between the plural first insulators. The method further includes etching the second and third insulators to form first to N-th contact holes respectively reaching the electrode layers under the first to N-th upper faces, and forming first to N-th contact plugs in the first to N-th contact holes respectively.

### First Embodiment

### (1) Structure of Semiconductor Device of First Embodiment

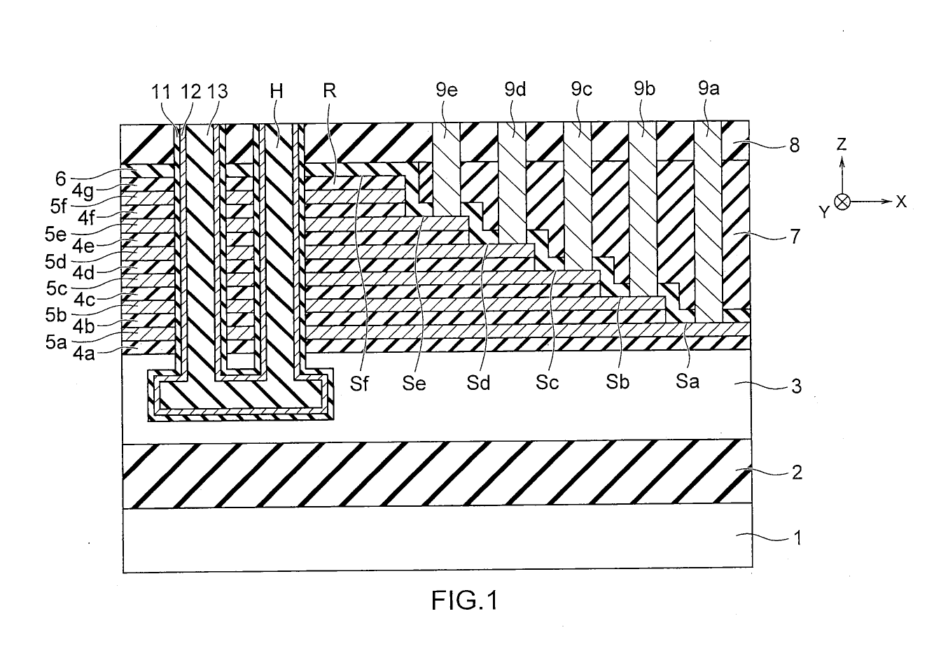

FIG. 1 is a cross-sectional view illustrating a structure of a semiconductor device of a first embodiment. FIG. 1 illustrates a three-dimensional memory and a step region for the three-dimensional memory.

The semiconductor device illustrated in FIG. 1 includes a substrate 1, an inter layer dielectric 2, an underlying semiconductor layer 3, plural first insulators 4a to 4g, plural electrode layers 5a to 5f, a second insulator 6, a third insulator 7, a fourth insulator 8, plural contact plugs 9a to 9e, a first memory insulator 11, a channel semiconductor layer 12 and a second memory insulator 13.

An example of the substrate 1 is a semiconductor substrate such as a silicon substrate. FIG. 1 illustrates an X direction and a Y direction which are parallel to a surface of the substrate 1 and perpendicular to each other, and a Z direction which is perpendicular to the surface of the substrate 1. In the present specification, the +Z direction is assumed as an upward direction and the −Z direction is assumed as a downward direction. For example, the positional relationship between the substrate 1 and the inter layer dielectric 2 is described that the substrate 1 is placed below the inter layer dielectric 2. The −Z direction in the preset embodiment may or may not match with the direction of gravity.

The inter layer dielectric 2 is formed on the substrate 1. An example of the inter layer dielectric 2 is a silicon oxide (SiO₂) film or a silicon nitride (SiN) film. The inter layer dielectric 2 may be a stack film including plural insulators. The inter layer dielectric 2 covers transistors and the like on the substrate 1.

The underlying semiconductor layer 3 is formed on the inter layer dielectric 2. An example of the underlying semiconductor layer 3 is a polysilicon layer.

The first insulators 4a to 4g and the electrode layers 5a to 5f are alternately stacked on the underlying semiconductor layer 3. An example of the first insulators 4a to 4g is SiO₂ films. An example of the electrode layers 5a to 5f is metal layers such as tungsten (W) layers. The electrode layers 5a to 5f function as word lines or select lines of the three-dimensional memory. The number of the first insulators 4a to 4g may be an integer other than seven, and the number of the electrode layers 5a to 5f may be an integer other than six. An example of the number of the first insulators 4a to 4g and the number of the electrode layers 5a to 5f is several tens.

The first insulators 4a to 4g and the electrode layers 5a to 5f include a step region R having upper faces Sa to Se whose heights are mutually different. The step region R is an example of a contact region. The upper faces Sa to Se are an example of first to N-th upper faces where N is an integer of two or more. The upper faces Sa to Se of the present embodiment are the upper faces of the electrode layers 5a to 5e, respectively. The step region R of the present embodiment further has an upper face Sf that is an upper face of the first insulator 4g.

The second insulator 6 is formed on the first insulators 4a to 4g and the electrode layers 5a to 5f, and covers the upper faces Sa to Sf of the step region R. The second insulator 2 is an insulator containing boron or hafnium. Examples of the second insulator 2 is a boron nitride (BN) film, a boron oxynitride (BON) film, and a hafnium oxide film (HfOₓ) film. In the present embodiment, the number of moles of boron atoms or hafnium atoms in the second insulator 6 is set equal to or larger than 10% and equal to or smaller than 50% of the number of moles of all the atoms in the second insulator 6.

The third insulator 7 is formed on the second insulator 6 to fill the space on the step region R. An example of the third insulator 7 is a SiO₂ film.

The fourth insulator 8 is formed on the substrate 1 to cover the first insulators 4a to 4g, the electrode layers 5a to 5f, the second insulator 6 and the third insulator 7. An example of the fourth insulator 8 is a SiO₂ film.

The contact plugs 9a to 9e are formed in the second to fourth insulators 6 to 8, and are electrically connected to the electrode layers 5a to 5e under the upper faces Sa to Se of the step region R respectively. The contact plugs 9a to 9e are an example of first to N-th contact plugs. Each of the contact plugs 9a to 9e of the present embodiment is formed of a barrier metal layer such as a titanium (Ti) layer and a plug material layer such as a W layer or aluminum (Al) layer.

The first memory insulator 11, the channel semiconductor layer 12 and the second memory insulator 13 form the three-dimensional memory. The first memory insulator 11, the channel semiconductor layer 12 and the second memory insulator 13 are an example of a first insulating layer, a semiconductor layer and a second insulating layer, respectively.

The first memory insulator 11 is formed on a surface of a hole H that penetrates the first insulators 4a to 4g and the electrode layers 5a to 5f. The hole H is also formed in the underlying semiconductor layer 3. The channel semiconductor layer 12 is formed on the surface of the hole H via the first memory insulator 11. The second memory insulator 13 is formed in the hole H via the first memory insulator 11 and the channel semiconductor layer 12. An example of the first and second memory insulators 11 and 13 is SiO₂ films. An example of the channel semiconductor layer 12 is a polysilicon layer.

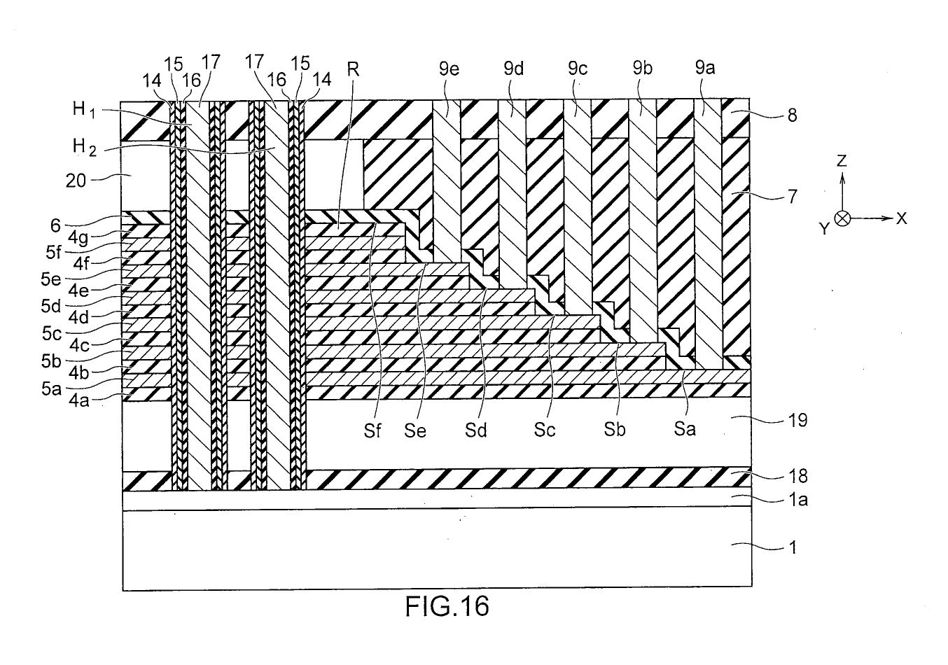

FIG. 16 is a cross-sectional view illustrating a structure of a semiconductor device of a modification of the first embodiment.

In FIG. 16, a first memory insulator 14, a charge storing layer 15, a second memory insulator 16 and a channel semiconductor layer 17 form a three-dimensional memory. The first second memory insulator 14, the second memory insulator 16 and the channel semiconductor layer 17 are an example of a first insulating layer, a second insulating layer and a semiconductor layer, respectively. The semiconductor device of FIG. 16 further includes an underlying insulator 18, a source conductive layer 19 and a drain conductive layer 20.

The underlying insulator 18 is formed on a diffusion layer la formed in the substrate 1. The source conductive layer 19 is formed on the underlying insulator 18. The first insulators 4a to 4g and the electrode layers 5a to 5f are alternately stacked on the source conductive layer 19. The drain conductive layer 20 is formed on the first insulators 4g via the second insulator 6.

The first memory insulator 14 is formed on surfaces of holes H₁ and H₂ that penetrate the first insulators 4a to 4g and the electrode layers 5a to 5f. The holes H₁ and H₂ are also formed in the underlying insulator 18, the source conductive layer 19 and the drain conductive layer 20. The first memory insulator 14 functions as a blocking insulator. An example of the first memory insulator 14 is a SiO₂ film.

The charge storing layer 15 is formed on the surfaces of the holes H₁ and H₂ via the first memory insulator 14. The charge storing layer 15 has a function to store charges. Examples of the charge storing layer 15 are a SiN film and a polysilicon layer.

The second memory insulator 16 is formed on the surfaces of the holes H₁ and H₂ via the first memory insulator 14 and the charge storing layer 15. The second memory insulator 16 functions as a tunnel insulator. An example of the second memory insulator 16 is a SiO₂ film.

The channel semiconductor layer 17 is formed in the holes H₁ and H₂ via the first memory insulator 14, the charge storing layer 15 and the second memory insulator 16. An example of the channel semiconductor layer 17 is a polysilicon layer.

The structure of the three-dimensional memory of the present modification can be also applied to the following second and third embodiments.

### (2) Method of Manufacturing Semiconductor Device of First Embodiment

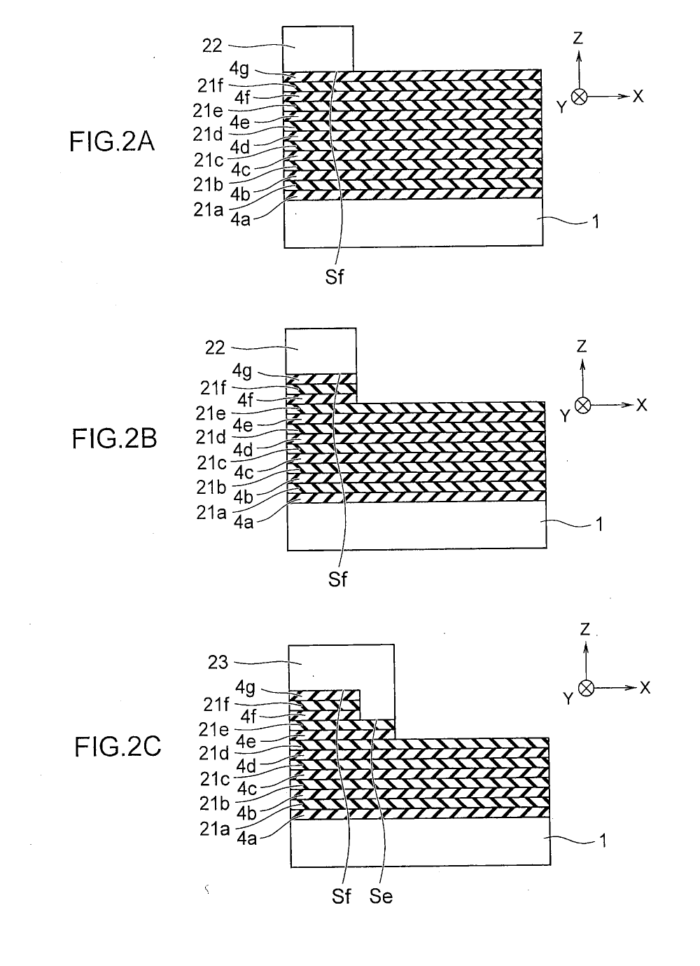

FIG. 2A to FIG. 5B are cross-sectional views illustrating a method of manufacturing the semiconductor device of the first embodiment.

First, the first insulators 4a to 4g and plural first films 21a to 21f are alternately formed on the substrate 1 via the inter layer dielectric 2 and the underlying semiconductor layer 3 which are not illustrated (FIG. 2A). An example of the first insulators 4a to 4g is SiO₂ films. An example of the first films 21a to 21f is SiN films. A resist layer 22 is then formed on the first insulator 4g to cover a range corresponding to the upper face Sf.

Next, the first insulator 4g, the first film 21f and the first insulator 4f are etched by using the resist layer 22 as a mask (FIG. 2B). Consequently, the upper face Sf is formed.

Next, a resist layer 23 is formed on the first insulator 4g and the first film 21e to cover the upper face Sf and a range corresponding to the upper face Se (FIG. 2C). The first film 21e and the first insulator 4e are then etched by using the resist layer 23 as a mask. Consequently, the upper face Se is formed.

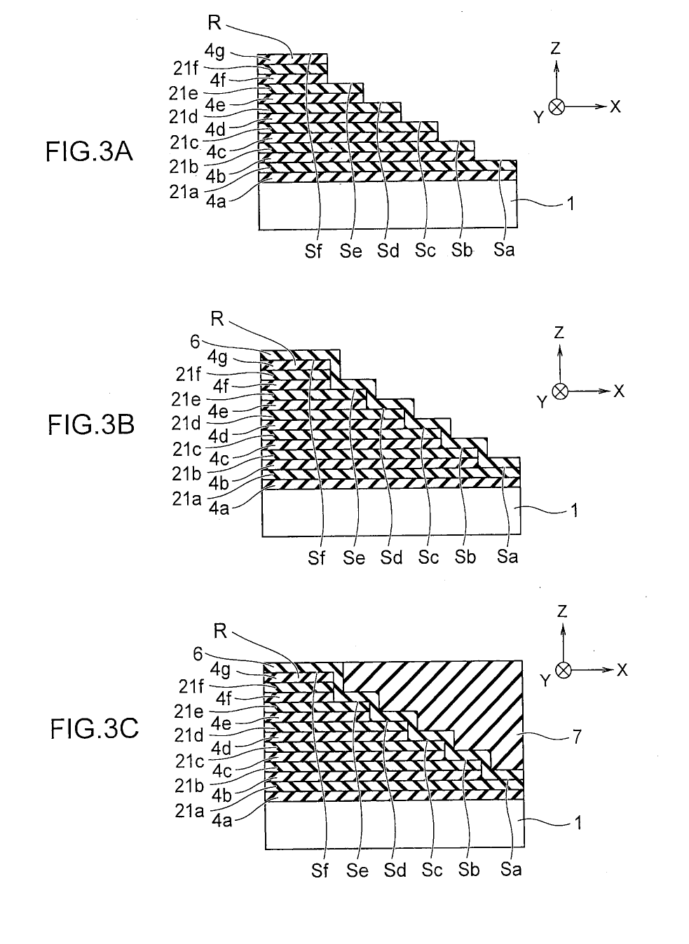

Next, processes similar to those in FIG. 2C are repeatedly performed on the first insulators 4a to 4d and the first films 21a to 21d. Consequently, the step region R having the upper faces Sa to Sf is formed (FIG. 3A). The upper faces Sa to Se are upper faces of the first films 21a to 21e, respectively. The upper face Sf is an upper face of the first insulator 4g.

Next, the second insulator 6 is formed on the first insulators 4a to 4g and the first films 21a to 21f having the step region R (FIG. 3B). Consequently, the upper faces Sa to Sf of the step region R are covered with the second insulator 6. Examples of the second insulator 6 are a BN film, a BON film and an HfOₓ film. The second insulator 6 is used as a stopper film for contact processing.

Next, the third insulator 7 is formed on the second insulator 6 to fill the space on the step region R (FIG. 3C). The third insulator 7 is formed by depositing the third insulator 7 on the substrate 1 and planarizing the surface of the third insulator 7 until the second insulator 6 appears by chemical mechanical polishing (CMP). An example of the third insulator 7 is a SiO₂ film.

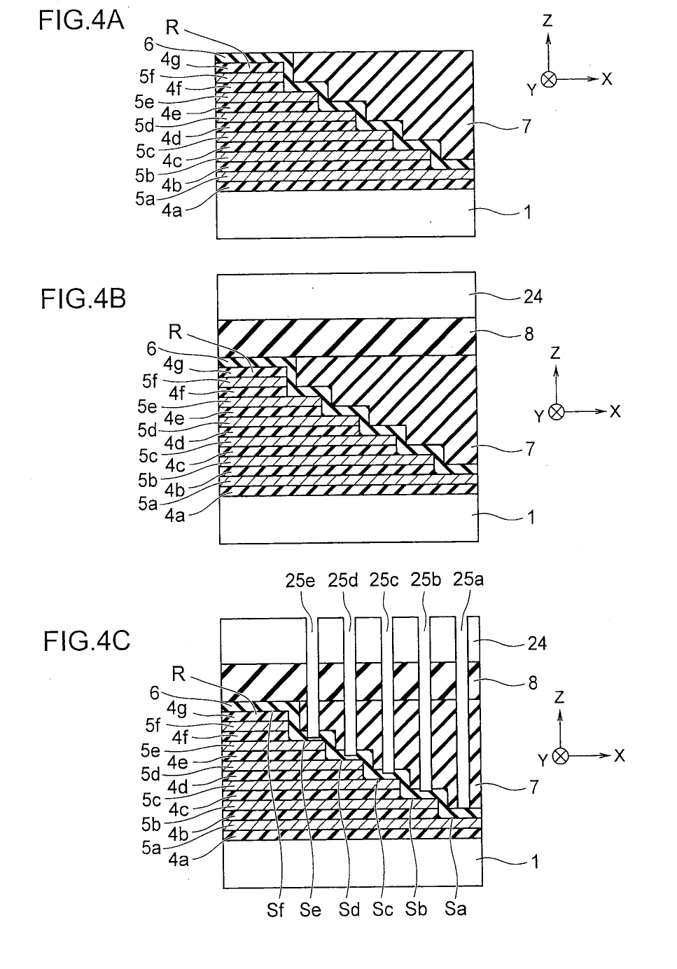

Next, a replace processing is performed to replace the first films 21a to 21f with the electrode layers 5a to 5f, respectively (FIG. 4A). An example of the electrode layers 5a to 5f are tungsten (W) layers.

The replace processing of the present embodiment is performed as below. First, the side faces of the first films 21a to 21f are exposed to the space on the substrate 1. Next, the side faces are subjected to a chemical solution to remove the first films 21a to 21f by the chemical solution. Consequently, cavities are formed between the first insulators 4a to 4g. Next, an electrode material for the electrode layers 5a to 5f is embedded in the cavities. Consequently, the electrode layers 5a to 5f are formed between the first insulators 4a to 4g.

In the replace processing of the present embodiment, a phosphoric acid (H₃PO₄) solution is used as the chemical solution. The phosphoric acid solution can remove the SiN film with the SiO₂ film left. Therefore, in the replace processing of the present embodiment, the first films 21a to 21f can be removed with the first insulators 4a to 4g left.

If the second insulator 6 is a SiN film, the second insulator 6 is removed by the chemical solution in the replace processing. However, a BN film, a BON film and an HfOₓ film which are examples of the second insulator 6 are resistant to the phosphoric acid solution. Therefore, in the replace processing of the present embodiment, the first films 21a to 21f can be remove with the second insulator 6 left.

The chemical solution in the replace processing of the present embodiment may be any liquid other than phosphoric acid solution capable of removing the first films 21a to 21f with the first insulators 4a to 4g and the second insulator 6 left.

The electrode material for the electrode layers 5a to 5f of the present embodiment may be a metal other than tungsten capable of being embedded in the cavities between the first insulators 4a to 4g.

When the first films 21a to 21f of the present embodiment are removed by the chemical solution, the first films 21a to 21f are removed to leave plural column portions at some places in the cavities in order to prevent the first insulators 4a to 4g from being broken due to the cavities.

Next, the fourth insulator 8 and a resist layer 24 are sequentially formed on the second and third insulators 6 and 7 (FIG. 4B). An example of the fourth insulator 8 is a SiO₂ film.

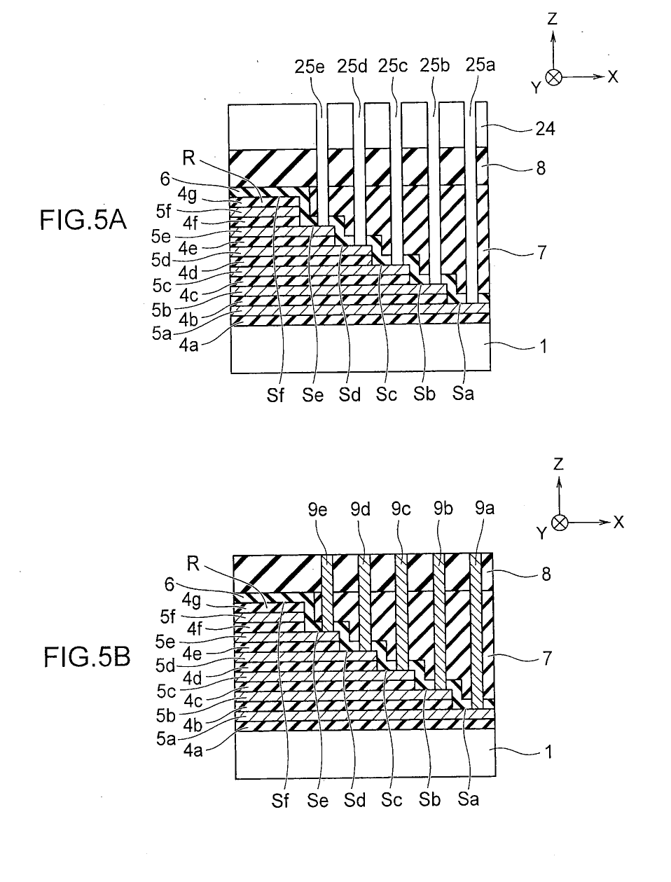

Next, first etching and second etching are performed by using the resist layer 24 as a mask. Specifically, the fourth insulator 8 and the third insulator 7 are etched in the first etching (FIG. 4C), and the second insulator 6 is etched in the second etching (FIG. 5A). Consequently, contact holes 25a to 25e respectively reaching the electrode layers 5a to 5e under the upper faces Sa to Se are formed. The contact holes 25a to 25e are an example of the first to N-th contact holes.

In the first etching of the present embodiment, the second insulator 6 is used as a stopper to etch the third and fourth insulators 7 and 8. Specifically, the third and fourth insulators 7 and 8 are etched at high etching selectivity of the third and fourth insulators 7 and 8 relative to the second insulator 6. Therefore, according to the present embodiment, a difference in the amount of over-etching between the contact holes 25a to 25e can be absorbed in the second insulator 6 (FIG. 4C).

The first etching of the present embodiment is performed by using a first gas. An example of the first gas is CF-based gas. The gas molecules in the CF-base gas are an example of a first gas molecule including a carbon atom and a fluorine atom.

In the second etching of the present embodiment, the second insulator 6 is etched at a high etching rate of the second insulator 6. Thereby, the contact holes 25a to 25e penetrating the second insulator 6 can be formed (FIG. 5A).

The second etching of the present embodiment is performed by using a second gas different from the first gas. An example of the second gas is a mixed gas containing a CF-based gas and a halogen-based gas. The gas molecules in the halogen-based gas are an example of a second gas molecule containing a halogen atom.

Next, the contact plugs 9a to 9e are formed in the contact holes 25a to 25e, respectively (FIG. 5B). For example, the contact plugs 9a to 9e are formed by forming a barrier metal layer on the side faces and bottom faces of the contact holes 25a to 25e, embedding a plug material layer in the contact holes 25a to 25e via the barrier metal layer, and planarizing the surfaces of the barrier metal layer and the plug material layer by CMP.

Thereafter, the three-dimensional memory and other structural objects are formed on the substrate 1. For example, in a case where the three-dimensional memory of FIG. 1 is formed, the memory is formed by forming the hole H that penetrates the first insulators 4a to 4g, the electrode layers 5a to 5f and the like and sequentially embedding the first memory insulator 11, the channel semiconductor layer 12 and the second memory insulator in the hole H. For example, in a case where the three-dimensional memory of FIG. 16 is formed, the memory is formed by forming the holes H₁ and H₂ that penetrates the first insulators 4a to 4g, the electrode layers 5a to 5f and the like and sequentially embedding the first memory insulator 14, the charge storing layer 15, the second memory insulator 16 and the channel semiconductor layer 17 in the holes H₁ and H₂. In this way, the semiconductor device of the present embodiment is manufactured.

As described above, in the present embodiment, the second insulator 6 containing boron or hafnium is formed on the step region R. When the third insulator 7 is a typical insulator such as a silicon oxide film or a silicon nitride film, the etching selectivity of the third insulator 7 relative to the second insulator 6 can be set high by using an insulator containing boron or hafnium as the second insulator 6. Therefore, according to the present embodiment, the second insulator 6 can be used as a stopper film for the contact processing, and the contact holes 25a to 25e can be formed with common etching. Furthermore, the present embodiment makes it possible to prevent a contact failure in the contact plugs 9a to 9e and short-circuit between the electrode layers 5a to 5f by using the second insulator 6 as a stopper film.

When the first films 21a to 21f are typical insulators such as silicon nitride films or silicon oxide films, the first films 21a to 21f can be removed with the second insulator 6 left with a proper chemical solution by using an insulator containing boron or hafnium as the second insulator 6. For example, when the first films 21a to 21f are silicon nitride films, a phosphoric acid solution can be used as the chemical solution. Therefore, the present embodiment makes it possible to leave the second insulator 6 in the replace processing and to prevent short-circuit between the electrode layers 5a to 5f.

In the present embodiment, even if the first films 21a to 21f are typical non-insulators such as polysilicon layers or amorphous silicon layers, the first films 21a to 21f can be removed with the second insulator 6 left by using a proper chemical solution. Therefore, the present embodiment makes it possible, even in such a case, to prevent short-circuit between the electrode layers 5a to 5f in the replace processing.

In the present embodiment, the number of moles K of boron atoms or hafnium atoms in the second insulator 6 is set equal to or larger than 10% and equal to or smaller than 50% of the number of moles Kₜₒₜ of all the atoms in the second insulator 6 (0.1≦K/Kₜₒₜ≦0.5). This is because the second insulator 6 is difficult to form in the case of K/Kₜₒₜ>0.5 and a difference between the etching rate of the second insulator 6 and the etching rate of a typical insulator is small in the case of K/Kₜₒₜ<0.1.

As described above, the present embodiment makes it possible, by forming the second insulator 6 containing boron or hafnium on the step region R, to form the contact plugs 9a to 9e normally functioning on the step region R through a small number of steps.

### Second Embodiment

### (1) Structure of Semiconductor Device of Second Embodiment

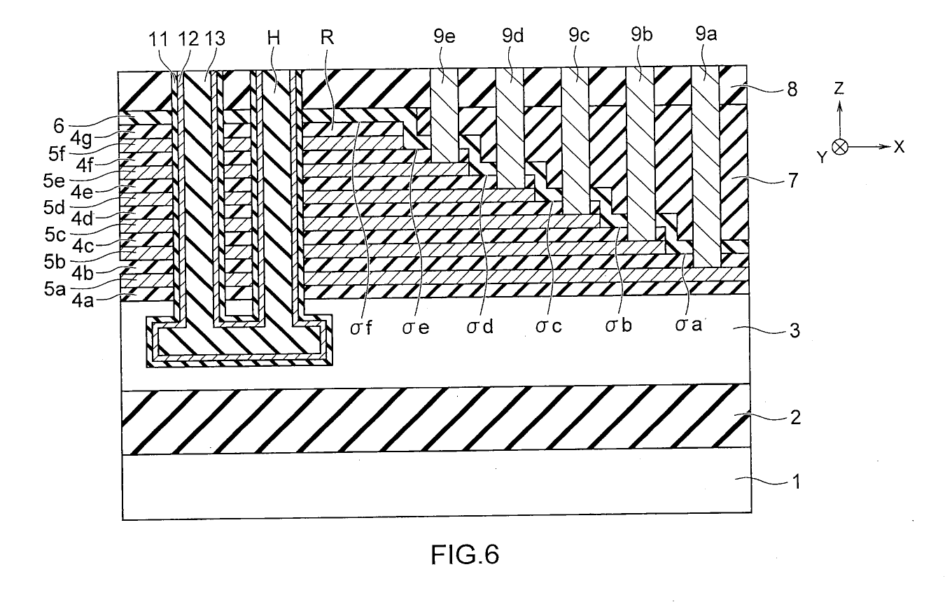

FIG. 6 is a cross-sectional view illustrating a structure of a semiconductor device of a second embodiment. Description will be omitted regarding components and manufacturing steps of the semiconductor device of the second embodiment which are same or similar to those of the first embodiment.

The step region R illustrated in FIG. 1 has the upper faces Sa to Sf whose heights are mutually different. On the other hand, the step region R illustrated in FIG. 6 has the upper faces σa to σf whose heights are mutually different. The upper faces σa to σf are upper faces of the first insulators 4b to 4g, respectively. The upper faces σa to σe are an example of the first to N-th upper faces. The upper face σf is the same face as the upper face Sf illustrated in FIG. 1.

The contact plugs 9a to 9e of the present embodiment are formed to penetrate the first insulators 4b to 4f, and are electrically connected to the electrode layers 5a to 5e under the upper faces σa to σe.

### (2) Method of Manufacturing Semiconductor Device of Second Embodiment

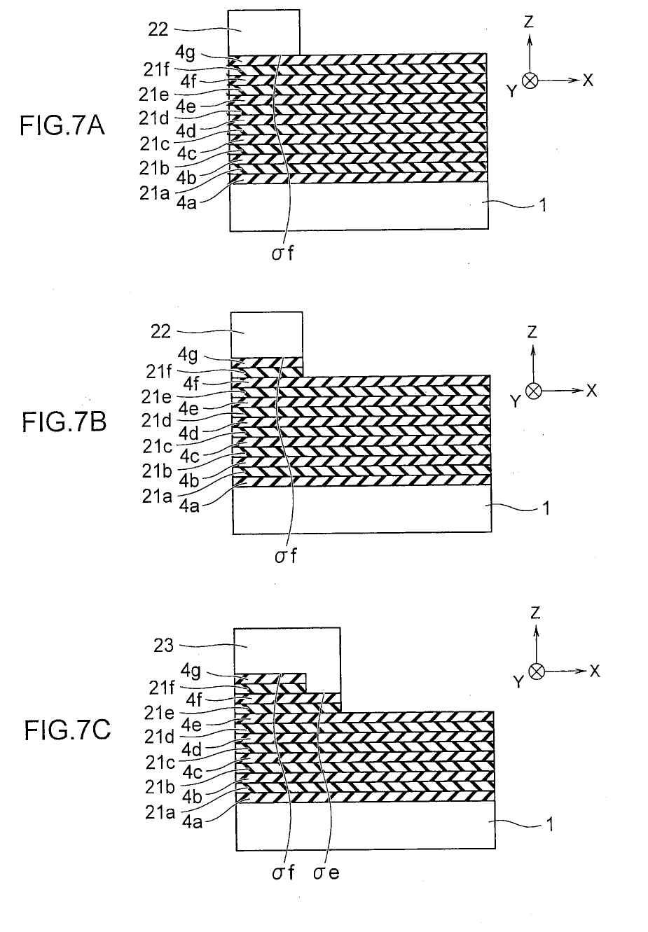

FIG. 7A to FIG. 10B are cross-sectional views illustrating a method of manufacturing the semiconductor device of the second embodiment.

First, the first insulators 4a to 4g and the first films 21a to 21f are alternately formed on the substrate 1 (FIG. 7A). Next, the resist layer 22 is formed on the first insulator 4g to cover a range corresponding to the upper face of. The resist layer 22 is then used as a mask to etch the first insulator 4g and the first film 21f (FIG. 7B). Consequently, the upper face σf is formed.

Next, the resist layer 23 is formed on the first insulators 4g and 4f to cover the upper face of and a range corresponding to the upper face σe (FIG. 7C). The resist layer 23 is then used as a mask to etch the first insulator 4f and the first film 21e. Consequently, the upper face σe is formed.

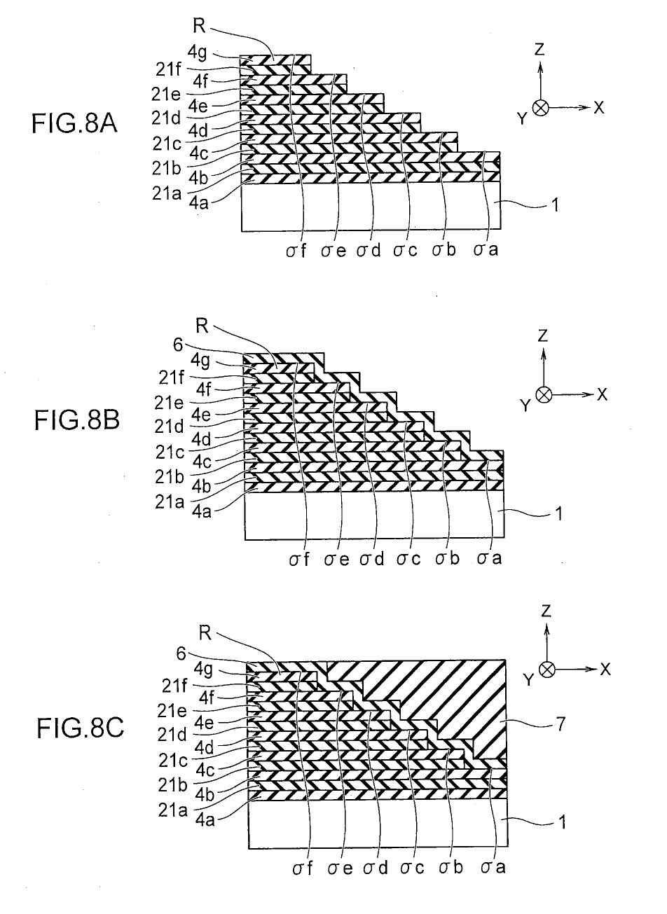

Next, processes similar to those in FIG. 7C are repeatedly performed on the first insulators 4a to 4e and the first films 21a to 21d. Consequently, the step region R with the upper faces σa to σf is formed (FIG. 8A).

Next, the second insulator 6 is formed on the first insulators 4a to 4g and the first films 21a to 21f having the step region R (FIG. 8B). Consequently, the upper faces σa to σf of the step region R are covered with the second insulator 6. Examples of the second insulator 6 are a BN film, a BON film and an HfOₓ film.

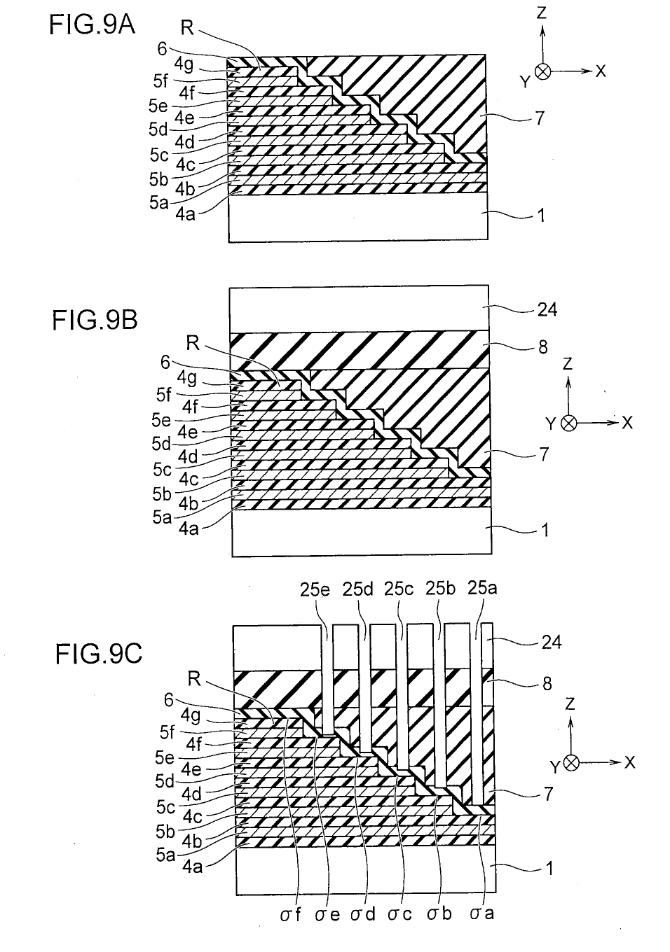

Next, the third insulator 7 is formed on the second insulator 6 to fill the space on the step region R (FIG. 8C). The replace processing is then performed to replace the first films 21a to 21f with the electrode layers 5a to 5f, respectively (FIG. 9A). The fourth insulator 8 and the resist layer 24 are then sequentially formed on the second and third insulators 6 and 7 (FIG. 9B).

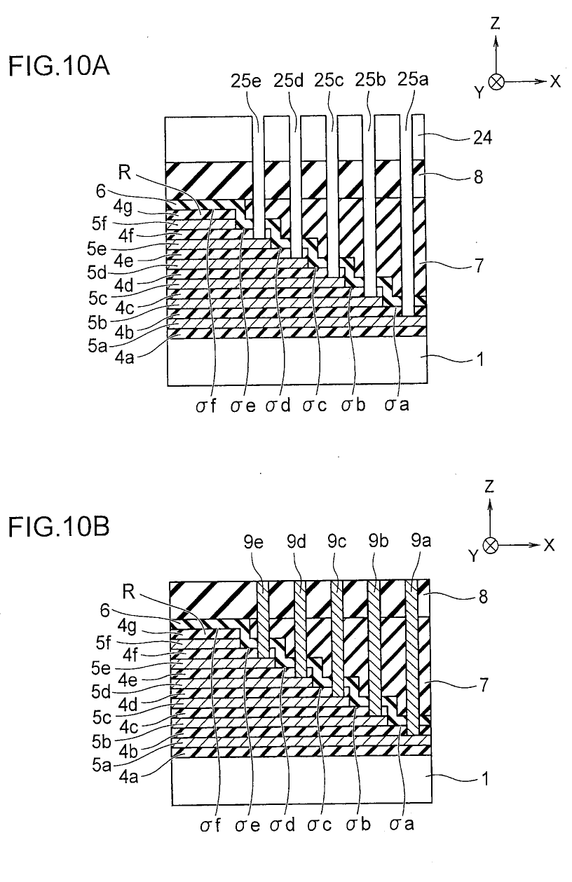

Next, first etching, second etching and third etching are performed by using the resist layer 24 as a mask. Specifically, the third and fourth insulators 7 and 8 are etched in the first etching (FIG. 9C), the second insulator 6 is etched in the second etching (FIG. 10A), and the first insulators 4b to 4f are etched in the third etching (FIG. 10A). Consequently, the contact holes 25a to 25e reaching the electrode layers 5a to 5e under the upper faces σa to σe are formed.

In the first etching of the present embodiment, the third and fourth insulators 7 and 8 are etched by using the second insulator 6 as a stopper. Specifically, the third and fourth insulators 7 and 8 are etched at high etching selectivity of the third and fourth insulators 7 and 8 relative to the second insulator 6. Therefore, according to the present embodiment, differences in amount of over-etching among the contact holes 25a to 25e can be reduced at the second insulator 6 (FIG. 9C). The first etching of the present embodiment is performed by using a first gas. An example of the first gas is a CF-based gas.

In the second etching of the present embodiment, the second insulator 6 is etched at a high etching rate of the second insulator 6. Thereby, the contact holes 25a to 25e penetrating the second insulator 6 can be formed (FIG. 10A). The second etching of the present embodiment is performed by using a second gas different from the first gas. An example of the second gas is a mixed gas containing a CF-based gas and a halogen-based gas.

In the third etching of the present embodiment, the first insulators 5b to 5f are etched at a high etching rate of the first insulators 5b to 5f. Thereby, the contact holes 25a to 25e penetrating the first insulators 5b to 5f can be formed (FIG. 10A). The third etching of the present embodiment is performed by using a third gas different from the second gas. An example of the third gas is a CF-based gas.

Next, the contact plugs 9a to 9e are formed in the contact holes 25a to 25e, respectively (FIG. 10B).

Thereafter, the three-dimensional memory and other structural objects are formed on the substrate 1. In this way, the semiconductor device of the present embodiment is manufactured.

Similarly to the first embodiment, the present embodiment makes it possible, by forming the second insulator 6 containing boron or hafnium on the step region R, to form the contact plugs 9a to 9e normally functioning on the step region R through a small number of steps.

When the first and second embodiments are compared, the first embodiment is advantageous in that the third etching is not required. On the other hand, the second embodiment is advantageous in that the electrode layers 5a to 5e do not need to be subjected to the second etching performed at a high etching rate.

### Third Embodiment

### (1) Structure of Semiconductor Device of Third Embodiment

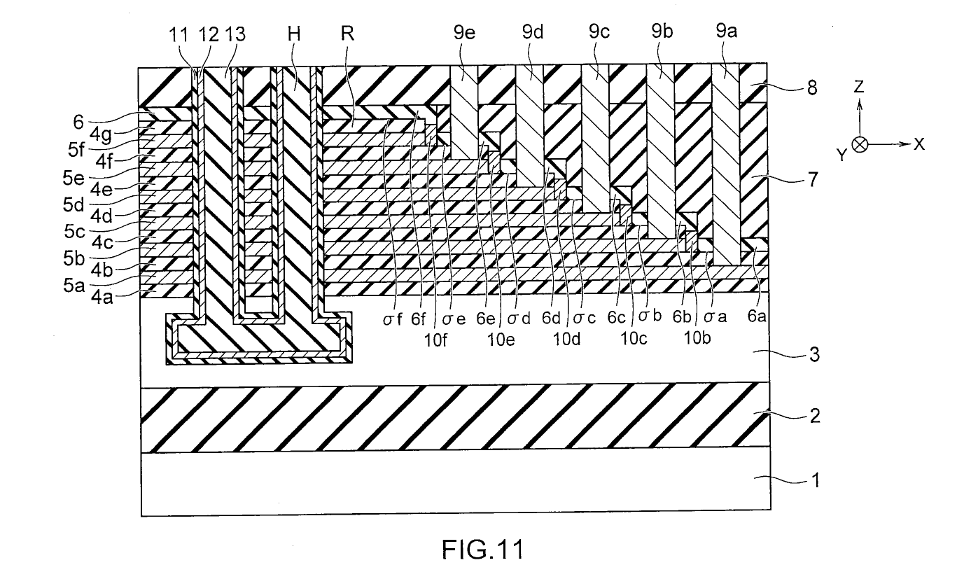

FIG. 11 is a cross-sectional view illustrating a structure of a semiconductor device of a third embodiment. Description will be omitted regarding components and manufacturing steps of the semiconductor device of the third embodiment which are same or similar to those of the first and second embodiments.

The step region R of the present embodiment has the upper faces σa to σf whose heights are mutually different as similar to the step region R of the second embodiment. The upper faces σa to σf are upper faces of the first insulators 4b to 4g, respectively.

The second insulator 6 of the present embodiment includes first to sixth portions 6a to 6f. The first to sixth portions 6a to 6f are formed on the upper faces σa to σf of the step region R, respectively. An example of the second insulator 6 of the present embodiment is a silicon boron nitride (SiBN) film. The contact plugs 9a to 9e are formed to penetrate the first to fifth portions 6a to 6e and the first insulators 4b to 4f, and are electrically connected to the electrode layers 5a to 5e under the upper faces σa to σe, respectively.

The electrode layers 5b to 5f of the present embodiment include electrode portions 10b to 10f, respectively. The electrode portions 10b to 10f are in contact with the side faces of the first to fifth portions 6a to 6e of the second insulator 6 and the lower faces of the second to sixth portions 6b to 6f of the second insulator 6, respectively. An example of the electrode layers 5b to 5f (including the electrode portions 10b to 10f) of the present embodiment are tungsten (W) layers.

### (2) Method of Manufacturing Semiconductor Device of Third Embodiment

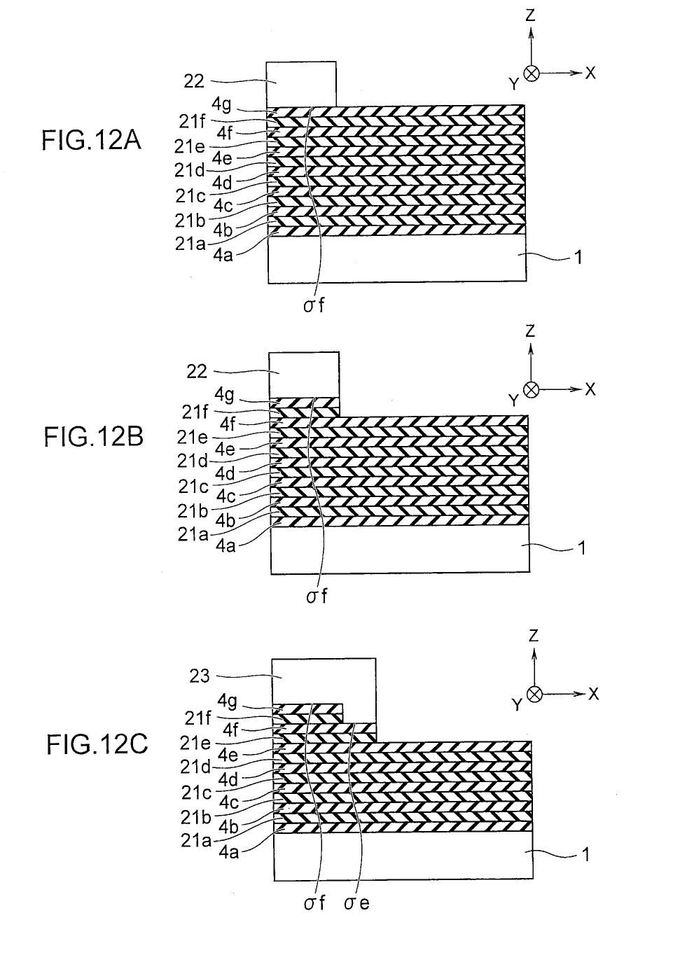

FIG. 12A to FIG. 15C are cross-sectional views illustrating a method of manufacturing the semiconductor device of the third embodiment.

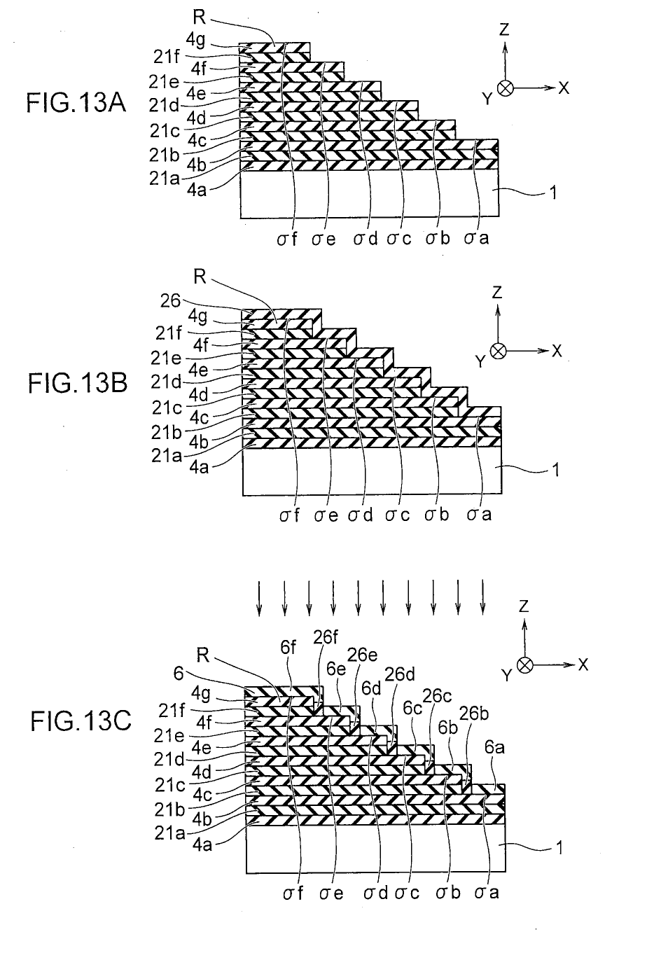

First, the steps in FIG. 12A to FIG. 13A are performed as in the steps in FIG. 7A to FIG. 8A. Consequently, the step region R having the upper faces σa to σf is formed (FIG. 13A).

Next, a second film 26 is formed on the first insulators 4a to 4g and the first films 21a to 21f having the step region R (FIG. 13B). Consequently, the upper faces σa to σf of the step region R is covered with the second film 26. An example of the second film 26 is a SiN film.

Next, boron is implanted into the second film 26 by ion implantation (FIG. 13C). Consequently, the second film 26 of the present embodiment changes to the second insulator 6 with the first to fifth portions 26b to 26f of the second film 26 left. Thereby, in the steps illustrated in FIG. 13C, the second insulator 6 including the first to sixth portions 6a to 6f is formed. When the second film 26 is a SiN film, an example of the second insulator 6 is a SiBN.

In the present embodiment, hafnium may be implanted into the second film 26 instead of boron. In this case, the second insulator 6 of the present embodiment is an insulator containing hafnium instead of boron.

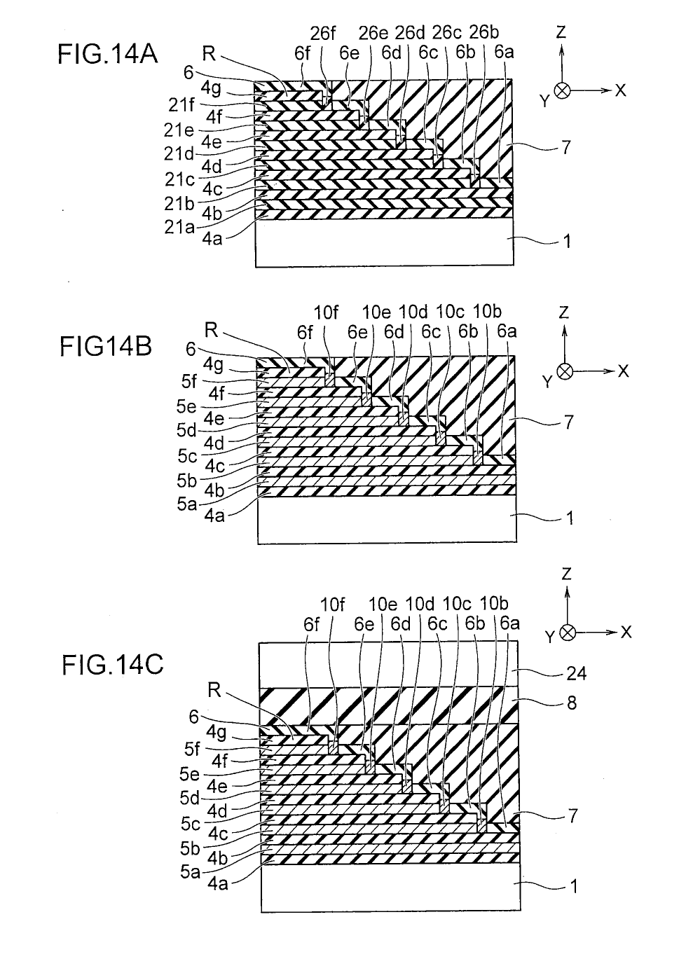

Next, the third insulator 7 is formed on the second insulator 6 to fill the space on the step region R (FIG. 14A).

Next, the replace processing is preformed to replace the first films 21a to 21f with the electrode layers 5a to 5f, respectively (FIG. 14B). The first films 21a to 21f and the second film 26 of the present embodiment are formed of the same material, specifically a SiN film. Therefore, in the replace processing of the present embodiment, the first films 21a to 21f and the first to fifth portions 26b to 26f of the second film 26 are removed together by using a phosphoric acid solution as the chemical solution. Consequently, when the electrode layers 5a to 5f are formed, the electrode portions 10b to 10f are formed in the regions from which the first to fifth portions 26b to 26f are removed, respectively.

On the other hand, the second insulator 6 of the present embodiment is a SiBN film and is therefore resistant to the phosphoric acid solution. Accordingly, in the replace processing of the present embodiment, the first films 21a to 21f and the first to fifth portions 26b to 26f of the second film 26 can be removed with the second insulator 6 left.

Next, the fourth insulator 8 and the resist layer 24 are sequentially formed on the second and third insulators 6 and 7 (FIG. 14C).

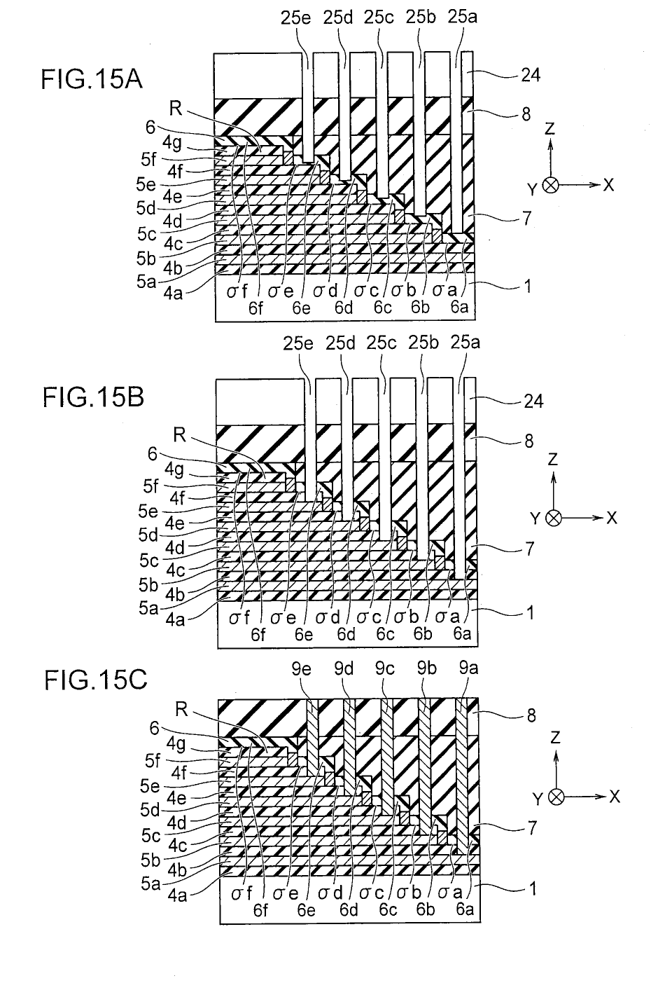

Next, the first etching, the second etching and the third etching are performed by using the resist layer 24 as a mask. Specifically, the third and fourth insulators 7 and 8 are etched in the first etching (FIG. 15A), the first to fifth portions 6a to 6e of the second insulator 6 are etched in the second etching (FIG. 15B), and the first insulators 4b to 4f are etched in the third etching (FIG. 15B). Consequently, the contact holes 25a to 25e reaching the electrode layers 5a to 5e under the upper faces σa to σe are formed. Examples of the first to third gases respectively used in the first to third etching are the same as those in the second embodiment.

In the present embodiment, the number of moles K of boron atoms or hafnium atoms in the first to fifth portions 6a to 6e is desirably equal to or larger than 10% and equal to or smaller than 50% of the number of moles Kₜₒₜ of all the atoms in the first to fifth portions 6a to 6e (0.1≦K/Kₜₒₜ≦0.5).

Next, the contact plugs 9a to 9e are formed in the contact holes 25a to 25e, respectively (FIG. 15C).

Thereafter, the three-dimensional memory and other structural objects are formed on the substrate 1. In this way, the semiconductor device of the present embodiment is manufactured.

Similarly to the first embodiment, the present embodiment makes it possible, by forming the second insulator 6 containing born or hafnium on the step region R, to form the contact plugs 9a to 9e normally functioning on the step region R through a small number of steps.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
alternately forming plural first insulators and plural first films on a substrate;
etching the first insulators and the first films to form a contact region having first to N-th upper faces whose heights are mutually different where N is an integer of two or more;
forming a second insulator containing boron or hafnium on the first to N-th upper faces;
forming a third insulator on the second insulator;
forming plural electrode layers between the plural first insulators;
etching the second and third insulators to form first to N-th contact holes respectively reaching the electrode layers under the first to N-th upper faces; and
forming first to N-th contact plugs in the first to N-th contact holes respectively.

2. The method of claim 1, wherein the plural electrode layers are formed by replacing the plural first films with the plural electrode layers.

3. The method of claim 1, wherein the first to N-th upper faces of the contact region are upper faces of the first films.

4. The method of claim 1, wherein the first to N-th upper faces of the contact region are upper faces of the first insulators.

5. The method of claim 4, wherein the first to N-th contact holes are formed by etching the first, second and third insulators.

6. The method of claim 1, wherein the second insulator is formed by forming a second film on the first to N-th upper faces and implanting boron or hafnium in the second film.

7. The method of claim 6, wherein the second film is formed of a same material as the first films.

8. The method of claim 6, wherein the plural electrode layers are formed by replacing the plural first films and plural portions of the second film with the plural electrode layers.

9. The method of claim 1, wherein the electrode layers are formed by removing the first films and embedding an electrode material in cavities formed by the removal of the first films.

10. The method of claim 1, wherein a number of moles of boron atoms or hafnium atoms in the second insulator is equal to or larger than 10% and equal to or smaller than 50% of a number of moles of all the atoms in the second insulator.

11. The method of claim 1, wherein the second insulator is a boron nitride film, a boron oxynitride film, a silicon boron nitride film or a hafnium oxide film.

12. The method of claim 1, wherein the first to N-th contact holes are formed by first etching to etch the third insulator by using a first gas and second etching to etch the second insulator by using a second gas different from the first gas.

13. The method of claim 12, wherein the first gas contains a first gas molecule containing a carbon atom and a fluorine atom.

14. The method of claim 12, wherein the second gas contains a first gas molecule containing a carbon atom and a fluorine atom and a second gas molecule containing a halogen atom.

15. The method of claim 1, further comprising:
forming a hole in the first insulators and the electrode layers; and
sequentially forming a first insulating layer, a semiconductor layer and a second insulating layer in the hole.

16. The method of claim 1, further comprising:
forming a hole in the first insulators and the electrode layers; and
sequentially forming a first insulating layer, a charge storing layer, a second insulating layer and a channel semiconductor layer in the hole.

17. A semiconductor device comprising:
a substrate;
plural first insulators and plural electrode layers alternately provided on the substrate and including a contact region having first to N-th upper faces whose heights are mutually different where N is an integer of two or more;
a second insulator provided on the first to N-th upper faces of the contact region and containing boron or hafnium;
a third insulator provided on the second insulator; and
first to N-th contact plugs provided in the second and third insulators, and electrically connected to the electrode layers under the first to N-th upper faces respectively.

18. The device of claim 17, wherein the first to N-th upper faces of the contact region are upper faces of the electrode layers.

19. The device of claim 17, wherein the first to N-th upper faces of the contact region are upper faces of the first insulators.

20. The device of claim 17, wherein the electrode layers are in contact with side faces and lower faces of the second insulator.
